(19) United States
(12) Patent Application Publication
(10) Pub. No.: US 2025/0166995 A1
(43) Pub. Date: May 22, 2025

(54) METHODS OF FORMING STRUCTURES INCLUDING VANADIUM BORIDE AND VANADIUM PHOSPHIDE LAYERS

(71) Applicant: ASM IP Holding B.V., Almere (NL)

(72) Inventors: Petro Deminskyi, Helsinki (FI); Charles Dezelah, Helsinki (FI); Jiyeon Kim, Phoenix, AZ (US); Giuseppe Alessio Verni, Ottignies (BE); Maart Van Druenen, Helsinki (FI); Qi Xie, Wilsele (BE); Petri Räisänen, Gilbert, AZ (US)

(21) Appl. No.: 19/034,986

(22) Filed: Jan. 23, 2025

Related U.S. Application Data
(62) Division of application No. 17/235,985, filed on Apr. 21, 2021, now Pat. No. 12,243,747.
(60) Provisional application No. 63/015,387, filed on Apr. 24, 2020.

(51) Int. Cl. H01L 21/28; C23C 16/38; C23C 16/455; C23C 16/50; H10D 64/66

(52) U.S. Cl. CPC H01L 21/28088; C23C 16/38; C23C 16/45525; C23C 16/50; H10D 64/667

(57) ABSTRACT

Methods and systems for depositing a layer, comprising one or more of vanadium boride and vanadium phosphide, onto a surface of a substrate and structures and devices formed using the methods are disclosed. An exemplary method includes using a deposition process. The deposition process can include providing a vanadium precursor to the reaction chamber and separately providing a reactant to the reaction chamber. Exemplary structures can include field effect transistor structures, such as gate all around structures. The layer comprising one or more of vanadium boride and vanadium phosphide can be used, for example, as barrier layers or liners, as work function layers, as dipole shifter layers, or the like.

### CROSS-REFERENCE TO RELATED APPLICATIONS

This application is a divisional of, and claims priority to, U.S. patent application Ser. No. 17/235,985, filed Apr. 21, 2021 and titled METHODS OF FORMING STRUCTURES INCLUDING VANADIUM BORIDE AND VANADIUM PHOSPHIDE LAYERS; which claims priority to U.S. Provisional Patent Application Ser. No. 63/015,387, filed Apr. 24, 2020 and titled METHODS OF FORMING STRUCTURES INCLUDING VANADIUM BORIDE AND VANADIUM PHOSPHODE LAYERS, the disclosures of which are hereby incorporated by reference in their entirety.

### FIELD OF INVENTION

The present disclosure generally relates to methods and systems suitable for forming a layer on a surface of a substrate and to structures including the layer. More particularly, the disclosure relates to methods and systems for forming layers that include vanadium boride and/or vanadium phosphide and to structures formed using the methods and systems.

### BACKGROUND OF THE DISCLOSURE

The scaling of semiconductor devices, such as, for example, complementary metal-oxide-semiconductor (CMOS) devices, has led to significant improvements in speed and density of integrated circuits. However, conventional device scaling techniques face significant challenges for future technology nodes.

For example, one challenge has been finding a suitable conducting material for use as a gate electrode in the CMOS devices. CMOS devices have conventionally used n-type doped polysilicon as the gate electrode material. However, doped polysilicon may not be an ideal gate electrode material for advanced node applications. Although doped polysilicon is conductive, there may still be a surface region which can be depleted of carriers under bias conditions. This region may appear as an extra gate insulator thickness, commonly referred to as gate depletion, and may contribute to the equivalent oxide thickness. While the gate depletion region may be thin, on the order of a few angstroms (Å), the gate depletion region may become significant as the gate oxide thicknesses are reduced in advanced node applications. As a further example, polysilicon does not exhibit an ideal effective work function (eWF) for both NMOS and PMOS devices. To overcome the non-ideal effective work function of doped polysilicon, a threshold voltage adjustment implantation may be utilized. However, as device geometries reduce in advanced node applications, the threshold voltage adjustment implantation processes may become increasingly complex and impractical.

To overcome problems associated with doped polysilicon gate electrodes, polysilicon gate material may be replaced with an alternative material, such as, for example, a metal, such as a titanium nitride layer. The titanium nitride layer may provide a more ideal effective work function for CMOS applications. However, in some cases, where higher work function values than those obtained with titanium nitride layers are desired, improved materials for gate electrodes are desired. Such materials may also be suitable for other applications, such as threshold voltage tuning or as a p-dipole shifter. In addition, improved layers for applications, such as diffusion barriers or liners, etch stop layers, electrodes, and the like, are also desired.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary introduces a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of forming a layer comprising one or more of vanadium boride and vanadium phosphide, to structures and devices formed using such methods, and to apparatus for performing the methods and/or for forming the structures and/or devices. The vanadium boride and/or vanadium phosphide layers can be used in a variety of applications, including gate stack metal layers, logic or memory (e.g., NAND, V-NAND, DRAM) electrode layer applications, as an etch stop layer (in front (FEOL), middle (MEOL), and/or back (BEOL) end of line processing), and/or as a diffusion barrier layer or liner. By way of particular examples, a vanadium boride and/or vanadium phosphide layer can be used as a work function metal (e.g., for an NMOS device), as a work function adjustment layer, as a voltage threshold adjustment layer, as a (e.g., p) dipole or flatband shifter layer, or the like.

Exemplary methods of forming a layer comprising one or more of vanadium boride and vanadium phosphide include providing a substrate within a reaction chamber of a reactor and, using a deposition process, depositing the layer comprising one or more of vanadium boride and vanadium phosphide onto a surface of the substrate. The deposition process can include (e.g., sequentially and separately) providing a vanadium precursor to the reaction chamber and providing one or more of a boron reactant and a phosphorus reactant to the reaction chamber. The vanadium precursor can include, for example, one or more of a vanadium halide, a vanadium oxyhalide, a vanadium organometallic compound, a vanadium metal organic compound, a vanadium beta-diketonate compound, a vanadium cyclopentadienyl compound, a vanadium alkoxide compound, a vanadium dialkylamido compound, a vanadium amidinate compound, a DAD ligand compound, where DAD is represented by 1,4-diaza-1,3-butadiene (RN=CR′CR′=NR, R=alkyl, aryl, R′=H, alkyl), and a vanadium heteroleptic or mixed ligand compound, or the like. The boron reactant can include one or more of a borane, a borohydride, a boron halide, an alkyl boron compound, an amino boron compound, an amido boron compound, a compound comprising one or more borane adducts, a compound comprising one or more borohydride adducts, a mixed substituted boron compound or the like. The phosphorus reactant comprises one or more of phosphine, tetraphosphorus (P₄), a phosphorus halide, an alkyl phosphorus compound, an amino phosphorus compound, an amido phosphorus compound, or the like. In accordance with further examples, the method can further include a step of providing a sulfur reactant to the reaction chamber—e.g., to form an intermediate vanadium sulfide layer that can be used to form a vanadium bromide and/or vanadium phosphide layer. Exemplary sulfur reactants suitable for the step of providing the sulfur reactant include hydrogen sulfide (H₂S), sulfur (e.g., S₈), sulfur halides, thiols (e.g., alkyl and aryl thiols), compounds including disulfide bonds, compounds including sulfur-alkyl group bonds, and compounds represented by the formula R—S—S—R′, wherein R and R′ are independently selected from aliphatic (e.g., C1-C8) and aromatic groups.

The deposition process may be a cyclical deposition process. The cyclical deposition process can include one or more of an atomic layer deposition process and a cyclical chemical vapor deposition process. The cyclical deposition process can include a thermal process—i.e., a process that does not use plasma-activated species. In some cases, a reactant and/or precursor can be exposed to a plasma to form activated reactant species.

In accordance with yet further exemplary embodiments of the disclosure, a structure is formed using a method as described herein. The structure can include a substrate and a layer comprising one or more of vanadium boride and vanadium phosphide formed overlying a surface of the substrate. Exemplary structures can further include one or more additional layers, such as an additional metal or conducting layer overlying the layer comprising one or more of vanadium boride and vanadium phosphide and/or one or more insulating or dielectric layers underneath or overlying the layer comprising one or more of vanadium boride and vanadium phosphide. The structure can be or form part of a CMOS structure, such as one or more of a PMOS and NMOS structure, or other device structure.

In one embodiment, the layer comprising one or more of vanadium boride and vanadium phosphide additionally comprises one or more other metal borides, such as a rare earth metal boride. Without limiting the current disclosure to any specific theory, the combination of vanadium boride and/or vanadium phosphide and the rare earth metal boride in a layer may lower the effective work function of the layer. Such a layer may be suitable for nMOS devices.

The layer may comprise vanadium boride and/or vanadium phosphide and a rare earth metal boride in variable proportions. The amount of vanadium boride and/or vanadium phosphide in a layer comprising rare earth metal boride may be between 0.01 at % and 85 at %, such as 0.05 at % or 75 at %. The amount of vanadium boride and/or vanadium phosphide in a layer comprising rare earth metal boride may be between 1% and 60 at %, for example 1.5 at %, 2 at %, 50 at % or 40 at %. The amount of vanadium boride and/or vanadium phosphide in a layer comprising rare earth metal boride may be between 5% and 35 at %, for example 6 at %, 7.5 at %, 10 at %, 20 at % or 25 at %.

In an embodiment, the layer comprising one or more of vanadium boride and vanadium phosphide comprises primarily one or more rare earth metal borides, and vanadium boride and/or vanadium phosphide is used to adjust the effective work function of the layer in a structure. By a layer comprising primarily of one or more rare earth metal borides is herein meant that it comprises at least 50 at % one or more rare earth metal boride. Thus, the rare earth metal boride may have a larger impact on the layer properties, while vanadium boride is used to adjust those properties. In such a case, the metal boride layer, for example a rare earth metal boride layer, may be doped with vanadium boride.

The rare earth metal boride may be, for example, a lanthanide boride, such as lanthanum boride, for example lanthanum hexaboride. The rare earth metal boride may be, for example a cerium boride, such as cerium hexaboride. The rare earth metal boride may be a neodymium boride, such as neodymium hexaboride. The rare earth metal boride may be a europium boride, such as europium hexaboride. The rare earth metal boride may be gadolinium boride, such as gadolinium hexaboride, or an erbium boride, such as erbium tetraboride or erbium hexaboride. Further, the rare earth metal boride may be scandium boride, such as scandium diboride or scandium hexaboride. The rare earth metal boride may be yttrium boride, such as yttrium hexaboride, yttrium diboride, yttrium tetraboride.

In addition to rare earth metal borides, vanadium boride may be included in layers comprising magnesium borides or manganese borides to lower their eWF as described above for rare earth metal borides.

In accordance with yet additional embodiments of the disclosure, a device or portion thereof can be formed using a method and/or a structure as described herein. Exemplary devices can include a substrate, an insulating or dielectric layer, a layer comprising one or more of vanadium boride and vanadium phosphide, and optionally an additional metal layer overlying the layer comprising one or more of vanadium boride and vanadium phosphide. The device can be or form part of, for example, a CMOS device.

In accordance with yet additional examples of the disclosure, a system to perform a method as described herein and/or to form a structure, device, or portion of either, is disclosed.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIGS. 1-3 illustrate methods in accordance with exemplary embodiments of the disclosure.

FIGS. 4-6 illustrate exemplary structures in accordance with embodiments of the disclosure.

FIG. 7 illustrates a reactor system in accordance with additional exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide methods for forming structures suitable for a variety of applications. Exemplary methods can be used to, for example, form a layer comprising one or more of vanadium boride and vanadium phosphide for metal oxides semiconductor (MOS) applications (e.g., as a work function layer and/or dipole or flatband shifter), such as in the formation of complimentary MOS (CMOS) devices, for use as etch stop layers, and/or for use as barrier or liner layers (e.g., in middle end of line (MEOL) and back end of line (BEOL) processing). For example, the layer comprising one or more of vanadium boride and vanadium phosphide can be used in the formation of logic devices, dynamic random-access memory (DRAM), three-dimensional NAND devices, as an NMOS work function metal layer, as a p-metal layer gate of a logic device, as a dipole layer for logic devices, or the like. However, unless noted otherwise, the invention is not necessarily limited to such examples.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert gases include helium, argon, and any combination thereof. In some cases, an inert gas can include nitrogen and/or hydrogen.

The term “purge” may refer to a procedure in which an inert or substantially inert gas is provided to a reactor chamber in between two pulses of gasses which react with each other. For example, a purge, or purging, e.g. using nitrogen gas, may be provided between pulses of two precursors, thus avoiding or at least minimizing gas phase interactions between the two precursors. It shall be understood that a purge can be effected either in time or in space, or both. For example in the case of temporal purges, a purge step can be used e.g. in the temporal sequence of providing a first precursor to a reactor chamber, providing a purge gas to the reactor chamber, and providing a second precursor to the reactor chamber, wherein the substrate on which a layer is deposited does not move. For example in the case of spatial purges, a purge step can take the following form: moving a substrate from a first location to which a first precursor is continually supplied, through a purge gas curtain, to a second location to which a second precursor is continually supplied.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or dielectric material layer overlying at least a portion of the bulk semiconductor material.

As used herein, the term “film” and/or “layer” can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

As used herein, a “structure” can be or include a substrate as described herein. Structures can include one or more layers overlying the substrate, such as one or more layers formed according to a method as described herein. Device portions can be or include structures.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, a “layer comprising vanadium boride” can be a material layer that can be represented by a chemical formula that includes vanadium and boron. In some cases, the layer comprising vanadium boride comprises vanadium diboride (VB₂). In some cases, the layer comprising vanadium boride comprises greater than 20 at %, greater than 50 at %, or greater than 80 at %, or greater than 90 at %, or greater than 95 at %, or greater than 99 at % vanadium diboride. In some embodiments, the layer comprising vanadium boride may consist essentially of vanadium boride. In some embodiments, the layer comprising vanadium boride may consist of vanadium boride. Layer consisting of vanadium boride may include an acceptable amount of impurities, such as oxygen, carbon, nitrogen, sulfur, phosphorus, chlorine or other halogen, and/or hydrogen that may originate from one or more precursors used to deposit the layer comprising vanadium boride.

As used herein, a “layer comprising vanadium phosphide” can be a material layer that can be represented by a chemical formula that includes vanadium and phosphorous. The layer comprising vanadium phosphide can include vanadium (III) phosphide (VP). In some cases, the layer comprising vanadium phosphide comprises greater than 20 at %, greater than 50 at %, or greater than 80 at %, or greater than 90 at %, or greater than 95 at %, or greater than 99 at % vanadium (III) phosphide. In some embodiments, the layer comprising vanadium phosphide may consist essentially of vanadium (III) phosphide. In some embodiments, the layer comprising vanadium phosphide may consist of vanadium (III) phosphide. Layer consisting of vanadium (III) phosphide may include an acceptable amount of impurities, such as oxygen, carbon, nitrogen, sulfur, boron, chlorine or other halogen, and/or hydrogen that may originate from one or more precursors used to deposit the layer comprising vanadium phosphide.

As used herein, a “vanadium precursor” includes a gas or a material that can become gaseous and that can be represented by a chemical formula that includes vanadium.

As used herein, a “vanadium halide precursor” includes a gas or a material that can become gaseous and that can be represented by a chemical formula that includes vanadium and a halogen, such as one or more of fluorine (F), chlorine (Cl), bromine (Br), and iodine (I).

The term “boron reactant” can refer to a gas or a material that can become gaseous and that can be represented by a chemical formula that includes boron.

The term “phosphorus reactant” can refer to a gas or a material that can become gaseous and that can be represented by a chemical formula that includes phosphorus.

The term “sulfur reactant” can refer to a gas or a material that can become gaseous and that can be represented by a chemical formula that includes sulfur.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

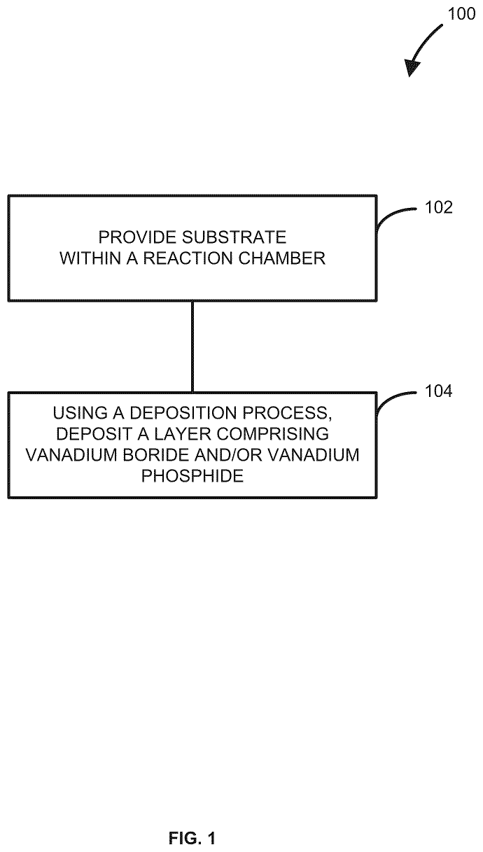

Turning now to the figures, FIG. 1 illustrates a method 100 in accordance with exemplary embodiments of the disclosure. Method 100 can be used to, for example, form a layer comprising one or more of vanadium boride and vanadium phosphide—i.e., the layer can include vanadium boride, vanadium phosphide, or both. The layer comprising one or more of vanadium boride and vanadium phosphide can be used during a formation of a device, such as a device noted herein. However, unless otherwise noted, methods are not limited to such applications.

Method 100 includes the steps of providing a substrate within a reaction chamber of a reactor (step 102) and depositing a layer comprising one or more of vanadium boride and vanadium phosphide onto a surface of the substrate (step 104).

During step 102, a substrate is provided within a reaction chamber. The reaction chamber used during step 102 can be or include a reaction chamber of a chemical vapor deposition reactor system configured to perform a deposition process. The deposition process may be a cyclical deposition process. The reaction chamber can be a standalone reaction chamber or part of a cluster tool.

Step 102 can include heating the substrate to a desired deposition temperature within the reaction chamber. In some embodiments of the disclosure, step 102 includes heating the substrate to a temperature of less than 800° C. For example, in some embodiments of the disclosure, heating the substrate to a deposition temperature may comprise heating the substrate to a temperature between approximately 20° C. and approximately 800° C., about 100° C. and about 400° C., about 20° C. and about 300° C., or about 20° C. and about 200° C.

In addition to controlling the temperature of the substrate, a pressure within the reaction chamber may also be regulated. For example, in some embodiments of the disclosure, the pressure within the reaction chamber during step 102 may be less than 760 Torr or between 0.2 Torr and 760 Torr, about 1 Torr and 100 Torr, or about 1 Torr and 10 Torr.

During step 104, the layer comprising one or more of vanadium boride and vanadium phosphide is deposited onto a surface of the substrate using a deposition process. As noted above, the deposition process may be a cyclical deposition process, and may include cyclical CVD, ALD, or a hybrid cyclical CVD/ALD process. For example, in some embodiments, the growth rate of a particular ALD process may be low compared with a CVD process. One approach to increase the growth rate may be that of operating at a higher deposition temperature than that typically employed in an ALD process, resulting in some portion of a chemical vapor deposition process, but still taking advantage of the sequential introduction of reactants. Such a process may be referred to as cyclical CVD. In some embodiments, a cyclical CVD process may comprise the introduction of two or more reactants into the reaction chamber, wherein there may be a time period of overlap between the two or more reactants in the reaction chamber resulting in both an ALD component of the deposition and a CVD component of the deposition. This is referred to as a hybrid process. In accordance with further examples, a cyclical deposition process may comprise the continuous flow of one reactant/precursor and the periodic pulsing of a second reactant into the reaction chamber. The temperature and/or pressure within a reaction chamber during step 104 can be the same or similar to any of the pressures and temperatures noted above in connection with step 102.

In accordance with some examples of the disclosure, the deposition process is a thermal deposition process. In these cases, the deposition process does not include use of a plasma to form activated species for use in the deposition process. For example, the deposition process may not comprise formation or use of plasma, may not comprise formation or use of excited species, and/or may not comprise formation or use of radicals. In the case of thermal cyclical deposition processes, a duration of the step of providing reactant to the reaction chamber can be relatively long to allow the reactant to react with the precursor or a derivative thereof. For example, the duration can be greater than or equal to 5 seconds or greater than or equal to 10 seconds or between about 5 and 10 seconds.

In other cases, a plasma can be used to excite one or more precursors, one or more reactants, and/or one or more inert gases.

The cyclical deposition process can include (e.g., separately and/or sequentially) providing a vanadium precursor to the reaction chamber and providing a boron and/or phosphorus reactant to the reaction chamber. In some cases, a hydrogen reactant can be provided to the reaction chamber with the vanadium precursor or with the boron and/or phosphorus reactant. The hydrogen reactant may comprise, for example, H₂ or excited, atomic, plasma or radical species of hydrogen.

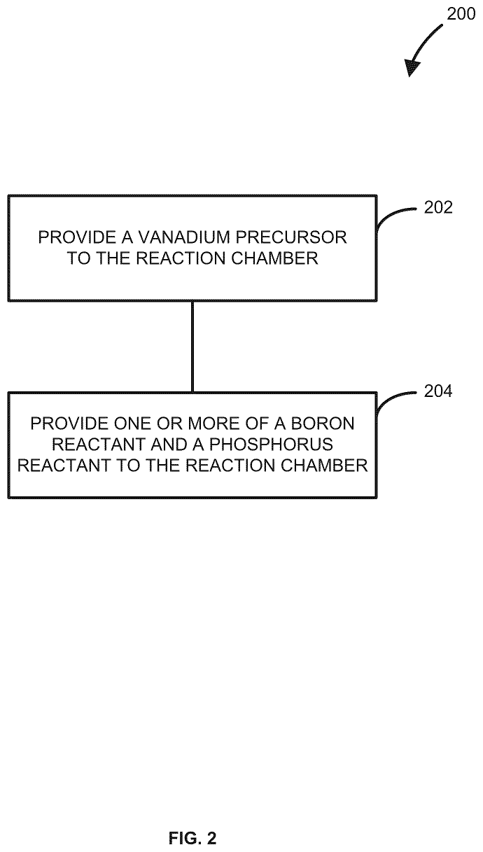

FIG. 2 illustrates an exemplary cyclical method 200 suitable for step 104 of method 100. Method 200 includes the steps of providing the vanadium precursor to the reaction chamber (step 202) and providing one or more of a boron reactant and a phosphorus reactant to the reaction chamber (step 204). In accordance with examples of the disclosure, during the step of providing one or more of a boron reactant and a phosphorus reactant to the reaction chamber (step 204), a layer comprising one or more of vanadium boride (e.g., comprising VB₂) and vanadium phosphide (e.g., comprising VP) is formed.

In some embodiments of the disclosure, method 100 includes repeating a unit deposition cycle that includes steps 202 and 204, with optional purge or move steps after step 202 and/or step 204. The deposition cycle can be repeated one or more times, based on, for example, desired thickness of the layer comprising one or more of vanadium boride and vanadium phosphide. For example, if the thickness of the layer comprising one or more of vanadium boride and vanadium phosphide layer is less than desired for a particular application, then steps 202 and 204 can be repeated one or more times.

The vanadium precursor can include one or more of a vanadium halide, a vanadium oxyhalide, a vanadium organometallic compound, a vanadium metal organic compound, a vanadium beta-diketonate compound, a vanadium cyclopentadienyl compound, a vanadium alkoxide compound, a vanadium dialkylamido compound, a vanadium amidinate compound, a DAD ligand compound, where DAD is represented by 1,4-diaza-1,3-butadiene (RN=CR′CR′=NR, R=alkyl, aryl, R′=H, alkyl), a vanadium heteroleptic or mixed ligand compound, or the like.

By way of particular examples, a vanadium halide can be selected from one or more of a vanadium fluoride, a vanadium chloride, a vanadium bromide, and a vanadium iodide. The vanadium halide can include only vanadium and one or more halogens—e.g., vanadium tetrachloride or the like. A vanadium oxyhalide can be selected from one or more vanadium oxyhalides, such as one or more of a vanadium oxyfluoride, a vanadium oxychloride, a vanadium oxybromide, and a vanadium oxyiodide. The vanadium oxyhalide can include only vanadium, oxygen, and one or more halides. By way of examples, the vanadium halide and oxyhalide can be selected from the group consisting of and include one or more of VCl₄, VBr₄, Vl₄, VOCl₄, VOBr₃, and VOl₃ (respectively named as vanadium tetrachloride, vanadium tetrabromide, vanadium tetraiodide, vanadiumoxytrichloride, vanadiumoxytribromide, and vanadiumoxytriiodide).

Exemplary vanadium beta-diketonate compounds include VO(acac)₂, VO(thd)₂, V(acac)₃, V(thd)₃ (respectively named as oxobis(2,4-pentanedionato)vanadium(IV), oxobis(2,2,6,6-tetramethyl-3,5-hepanedionato)vanadium(IV), tris(2,4-pentanedionato) vanadium(IV), and tris(2,2,6,6-tetramethyl-3,5-hepanedionato)vanadium(IV)), and/or VO(hfac)₂ or V(hfac)₃, where hfac is a hexaflouroacetylacetonato ligand, and the like.

Exemplary vanadium cyclopentadienyl compounds include VCp₂Cl₂, VCp₂, VCp₂(CO)₄, and VCpCl₃, (respectively named as bischlorobis(cyclopentdienyl)vanadium(IV), bis(cyclopentadienyl)vanadium(II), cyclopentadienylvanadium tetracarbonyl, and trichloro(cyclopentadienyl)vanadium(IV)). Additional exemplary vanadium cyclopentadienyl compounds include variations of these compounds, where Cp is either unsubstituted or bearing one or more alkyl groups, e.g., MeCp, EtCp, iPrCp, and the like.

Exemplary vanadium alkoxide compounds include V(OMe)₄, V(OEt)₄, V(OiPr)₄, V(OtBu)₄, VO(OMe)₃, VO(OEt)₃, VO(OiPr)₃, and VO(OtBu)₃, (respectively named as tetrakis(methoxy)vanadium(IV), tetrakis(ethoxy)vanadium(IV), tetrakis(isopropoxy)vanadium(IV), tetrakis(t-butoxy)vanadium(IV), oxotris(methoxy)vanadium(IV), oxotris(ethoxy)vanadium(IV), oxotris(isopropoxy)vanadium(IV), and oxotris(t-butoxy)vanadium (IV)). Additional vanadium alkoxide compounds include variations of these compounds, where other alkoxy ligands are used.

Exemplary vanadium dialkylamido compounds include V(NMe₂)₄, V(NEt₂)₄, and V(NEtMe)₄, (respectively named as tetrakis(dimethylamido)vanadium(IV), tetrakis(diethylamido)vanadium(IV), and tetrakis(ethylmethylamido)vanadium(IV)).

Exemplary amidinate compounds include V(iPrFMD)₃, V(iPrAMD)₃, V(tBuFMD)₃, and V(tBuAMD)₃, where iPrFMD is an N,N′-diisopropylformamidinato ligand, iPrAMD is an N,N′-diisopropylacetamidinato ligand, tBuFMD is an N,N′-di-tert-butylformamidinato ligand, and tBuAMD is an N,N′-di-tert-butylacetamidinato ligand.

Examples of precursors including a DAD ligand include V(DAD)₂, V(DAD)(CO)₄, VCp(DAD)(CO)₂, V(DAD)Cl₃, and V(DAD)₂(NO)₂, where DAD is 1,4-diaza-1,3-butadiene (RN=CR′CR′=NR, where R=alkyl or an aryl group, and R′=H, or an alkyl group).

Further, exemplary vanadium precursors can include “heteroleptic” or mixed ligand precursors, where any combination of the exemplary ligand types in any attainable number (typically 3-5 ligands, but there can be exceptions) can be attached to the vanadium atom. Examples could include V(Cl)ₓ(NMe)₄₋ₓ and V(Cl)ₓ(iPrAMD)ₓ.

Use of vanadium halide precursors can be advantageous relative to methods that use other precursors, such as vanadium metalorganic precursors, because the vanadium halide precursors can be relatively inexpensive, can result in vanadium layers with lower concentrations of impurities, such as carbon, and/or processes that use such precursors can be more controllable-compared to processes that use metalorganic or other vanadium precursors. Further, such reactants can be used without the assistance of a plasma to form excited species. In addition, processes that use vanadium halide may be easier to scale up, compared to methods that use organometallic vanadium precursors.

Exemplary boron reactants include boranes, borohydrides, boron halides, alkyl boron compounds, amino boron compounds, amido boron compounds, compounds comprising one or more borane adducts, compounds comprising one or more borohydride adducts, mixed substituted boron compounds, and the like.

Exemplary boranes can be represented by a general formula: BₙHₙ₊ₓ, where n and x are integers greater than or equal to 1. For example, a borane can be or include diborane (B₂H₆), tetraborane (B₄H₁₀), pentaborane (B₅H₉), decaborane (B₁₀H₁₄), or the like.

Exemplary boron halides include BF₃, BCl₃, BBr₃, Bl₃, and the like.

Exemplary compounds s including borane/borohydride include BH₃(NHMe₂), BH₃(SMe₂), BH₃(tetrahydrofuran), pinacolborane, BH₃(2-picoline), and the like.

Exemplary alkyl boron compounds include BEt₃ and the like.

Exemplary amino boron compounds/amido boron compounds include B(NMe₂)₃ and the like.

Exemplary mixed substituted boron compounds include BBr (NMe₂)₂, BCl₂(NiPr₂), BHBr₂(SMe₂), and the like.

Exemplary phosphorus reactants can be selected from one or more of phosphine, tetraphosphorus (P₄), phosphorus halides, alkyl phosphorus compounds, amino phosphorus compounds, and amido phosphorus compounds.

Exemplary phosphorus halides include PCl₃, PCl₅, PBr₃, PBr₅, and the like.

Exemplary alkyl phosphorus compounds include PMe₃, PEt₃, tBuPH₂, iPrPH₂, and the like.

Exemplary amino phosphorus compounds/amido phosphorus compounds include P(NMe₂)₃ and the like.

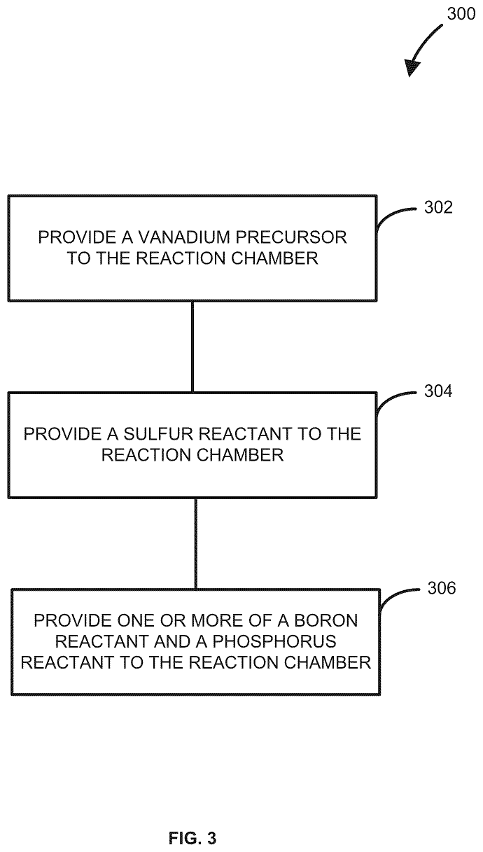

In accordance with additional examples of the disclosure, method 100 can include an intermediate step of forming a sulfide (e.g., V₂S₃). FIG. 3 illustrates a method 300, suitable for step 104, that includes the steps of providing the vanadium precursor to the reaction chamber (step 302), providing a sulfur reactant to the reaction chamber (step 304) and providing one or more of a boron reactant and a phosphorus reactant to the reaction chamber (step 306). Step 302 can be the same or similar to step 202 described above.

During step 304, a sulfur precursor is provided to the reaction chamber. During this step, a vanadium sulfide (e.g., comprising V₂S₃) can form. Steps 302 and 304 can be repeated a number of times to form a desired thickness of the vanadium sulfide.

During step 306, the boron reactant and/or phosphorus reactant are provided to the reaction chamber to form the layer comprising one or more of vanadium boride and vanadium phosphide. Step 306 can be repeated a number of times and steps 302-306 can be repeated to form the layer comprising one or more of vanadium boride and vanadium phosphide.

Exemplary sulfur reactants suitable for use during step 304 include hydrogen sulfide (H₂S), sulfur (e.g., S₈), thiols (e.g., alkyl and aryl thiols), compounds including disulfide bonds, compounds including a sulfur-alkyl group bond, and compounds represented by the formula R—S—S—R′ or S—R, wherein R and R′ are independently selected from aliphatic (e.g., C1-C8) and aromatic groups, sulfur halides (e.g., including one sulfur, such as SCl₂ or SBr₂, or one halide, such as disulfur dichloride). The alky thiols can include C1-C8 alkyl thiols.

Referring to FIGS. 1-3, the reaction chamber can be purged using a vacuum and/or an inert gas to, for example, mitigate gas phase reactions between reactants and enable self-saturating surface reactions—e.g., in the case of ALD—before or after one or more steps. For example, the reaction chamber can be purged following one or more of steps 202, 204, 302, 304, and/or 306. Additionally or alternatively, the substrate may be moved to separately contact a first vapor phase reactant and a second vapor phase reactant. Surplus chemicals and reaction byproducts, if any, can be removed from the substrate surface or reaction chamber, such as by purging the reaction space or by moving the substrate, before the substrate is contacted with the next reactive chemical. The reaction chamber can be purged after the step of providing a precursor to the reaction chamber and/or after the step of providing a reactant to the reaction chamber.

In some embodiments, a step coverage of the layer comprising one or more of vanadium boride and vanadium phosphide is equal to or greater than about 50%, or greater than about 80%, or greater than about 90%, or about 95%, or about 98%, or about 99% or greater, in/on structures having aspect ratios (height/width) of more than about 2, more than about 5,more than about 10, more than about 25, more than about 50, more than about 100, or between about 10 and 100 or about 5 to about 25.

A growth rate of the layer comprising one or more of vanadium boride and vanadium phosphide can be relatively low—e.g., less 3 angstroms/cycle, between about 0.2 and 3 angstroms/cycle, or about 0.1 to about 1 angstrom/cycle. The relatively low growth rate can facilitate desired accuracy of film thickness and/or film thickness uniformity.

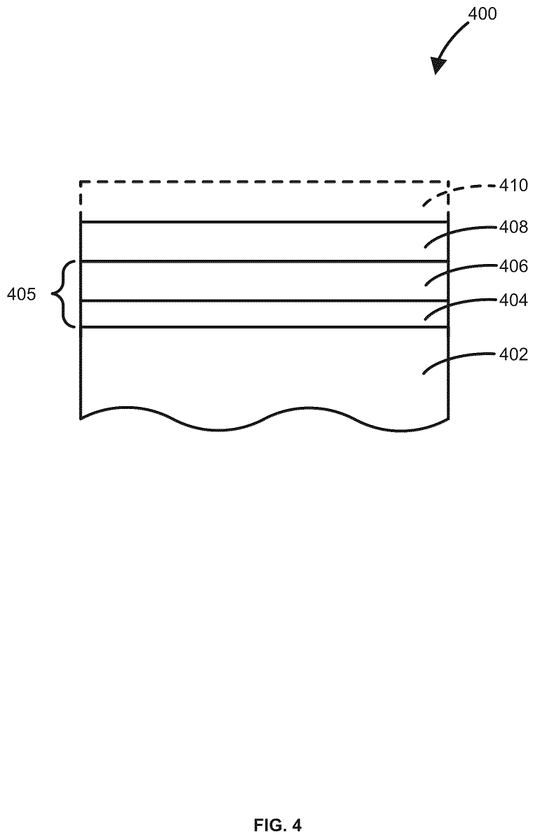

FIG. 4 illustrates a structure/a portion of a device 400 in accordance with additional examples of the disclosure. Device or structure 400 includes a substrate 402, dielectric or insulating material 405, and a layer comprising one or more of vanadium boride and vanadium phosphide 408. In the illustrated example, structure 400 also includes an additional conducting layer 410.

Substrate 402 can be or include any of the substrate material described herein.

Dielectric or insulating material 405 can include one or more dielectric or insulating material layers. By way of example, dielectric or insulating material 405 can include an interface layer 404 and a high-k material 406 deposited overlying interface layer 404. In some cases, interface layer 404 may not exist or may not exist to an appreciable extent. Interface layer 404 can include an oxide, such as a silicon oxide, which can be formed on a surface of the substrate 402 using, for example, a chemical oxidation process or an oxide deposition process. High-k material 406 can be or include, for example, a metallic oxide having a dielectric constant greater than about 7. In some embodiments, the high-k material has a dielectric constant higher than the dielectric constant of silicon oxide. Exemplary high-k materials include one or more of hafnium oxide (HfO₂), tantalum oxide (Ta₂O₅), zirconium oxide (ZrO₂), titanium oxide (TiO₂), hafnium silicate (HfSiOₓ), aluminum oxide (Al₂O₃), lanthanum oxide (La₂O₃), and mixtures/laminates comprising one or more such layers.

Layer comprising one or more of vanadium boride and vanadium phosphide 408 can be formed according to a method described herein. Because layer comprising one or more of vanadium boride and vanadium phosphide 408 is formed using a cyclical deposition process, a concentration of vanadium, boron, phosphorus, and/or other constituents in layer comprising one or more of vanadium boride and vanadium phosphide 408 can vary from a bottom of layer comprising one or more of vanadium boride and vanadium phosphide 408 to a top of layer comprising one or more of vanadium boride and vanadium phosphide 408 by, for example, controlling an amount of vanadium precursor and/or reactant(s) and/or respective pulse times or number of pulses during one or more deposition cycles. In some cases, layer comprising one or more of vanadium boride and vanadium phosphide 408 can have a stochiometric composition. A work function and other properties of layer comprising one or more of vanadium boride and vanadium phosphide 408 can be altered by altering an amount of vanadium, boron, phosphorus, and/or other compounds in the layer or in a deposition cycle.

Layer comprising one or more of vanadium boride and vanadium phosphide 408 can include impurities, such as halides, hydrogen or the like in an amount of less than one atomic percent, less than 0.2 atomic percent, or less than 0.1 atomic percent, or less than 0.05 atomic percent, alone or combined.

A thickness of layer comprising one or more of vanadium boride and vanadium phosphide 408 can vary according to application. By way of examples, a thickness of layer comprising one or more of vanadium boride and vanadium phosphide 408 can be less than 5 nm or about 0.1 nm to about 10 nm, or about 0.1 nm to about 5 nm, or about 0.2 nm to about 5 nm, or about 0.3 nm to about 3 nm, or about 0.3 nm to about 1 nm. When used to replace layers that may include aluminum, rather than vanadium, layer comprising one or more of vanadium boride and vanadium phosphide 408 may be relatively thin, which may be desirable for many applications, including work function and/or voltage threshold adjustment layers. In some cases, a thickness of layer comprising one or more of vanadium boride and vanadium phosphide 408 can be greater than 2 nm—e.g., when layer comprising one or more of vanadium boride and vanadium phosphide 408 is used as a barrier layer or liner.

A work function of a shifted layer comprising one or more of vanadium boride and vanadium phosphide 408 can be >4.6 eV, >4.7 eV, >4.8 eV, >4.9 eV, >4.95 eV, or >5.0 eV. A work function value of a device can be shifted by about 30 meV to about 400 meV, or about 30 meV to about 200 meV, or about 50 meV to about 100 meV using a layer comprising one or more of vanadium boride and vanadium phosphide as described herein. A thickness and/or composition of the layer comprising one or more of vanadium boride and vanadium phosphide can be manipulated to obtain a desired shift in work function and/or threshold voltage.

Additionally or alternatively, layer comprising one or more of vanadium boride and vanadium phosphide 408 can form a continuous film—e.g., using method 100—at a thickness of <5 nm, <4 nm, <3 nm, <2 nm, <1.5 nm, <1.2 nm, <1.0 nm, or <0.9 nm. Layer comprising one or more of vanadium boride and vanadium phosphide 408 can be relatively smooth, with relatively low grain boundary formation. In some cases, layer comprising one or more of vanadium boride and vanadium phosphide 408 may be amorphous, with relatively low columnar crystal structures (as compared to TiN). RMS roughness of exemplary layer comprising one or more of vanadium boride and vanadium phosphide 408 can be <1.0 nm, <0.7 nm, <0.5 nm, <0.4 nm, <0.35 nm, or <0.3 nm, at a thickness of less than 10 nm.

Additional conducting layer 410 can include, for example, metal, such as a refractory metal or the like. By way of examples, conducting layer 410 can be or include one or more of titanium nitride; vanadium nitride; a metal stack including titanium nitride and a metal (e.g., W, Co, Ru, Mo) or titanium nitride, titanium aluminum carbon, and titanium nitride; tungsten; tungsten carbon nitride; cobalt; copper; molybdenum, ruthenium; or the like.

Although illustrated with layer comprising one or more of vanadium boride and vanadium phosphide 408 overlying dielectric or insulating material 405, in some cases, layer comprising one or more of vanadium boride and vanadium phosphide 408 can additionally or alternatively be formed directly over substrate 402 (which can include various layers and/or topologies) and/or underlying dielectric or insulating material 405, between interface layer 404 and high-k material 406, and/or between layers of high-k material 406. Further, layer comprising one or more of vanadium boride and vanadium phosphide 408 may be deposited and at least partially removed, such that resultant structures may no longer include layer comprising one or more of vanadium boride and vanadium phosphide 408 or include a lesser number of layers comprising one or more of vanadium boride and vanadium phosphide than were initially formed on the structure.

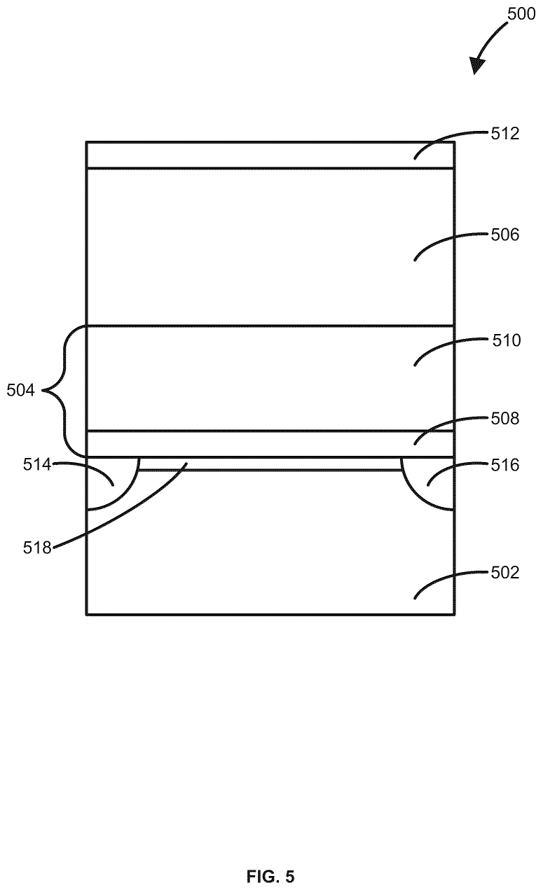

FIG. 5 illustrates another exemplary structure 500 in accordance with examples of the disclosure. Device or structure 500 includes a substrate 502, dielectric or insulating material 504, and layer comprising one or more of vanadium boride and vanadium phosphide 506. In the illustrated example, structure 500 also includes an additional conducting layer 512. Substrate 502, dielectric or insulating material 504, layer comprising one or more of vanadium boride and vanadium phosphide 506, and an additional conducting layer 512 can be the same or similar to substrate 402, dielectric or insulating material 405, vanadium and/or layer comprising one or more of vanadium boride and vanadium phosphide 408 and conducting layer 410. Similar to above, layer comprising one or more of vanadium boride and vanadium phosphide 506 can additionally or alternatively be formed overlying substrate 502 (which can include various layers and/or topologies) and/or underlying insulating material 504, between interface layer 508 and high-k material 510, and/or between layers of high-k material 510. Further, layer comprising one or more of vanadium boride and vanadium phosphide 506 may be deposited and at least partially removed, such that resultant structures may no longer include layer comprising one or more of vanadium boride and vanadium phosphide 506 or include a lesser number of layers comprising one or more of vanadium boride and vanadium phosphide 506 than were initially formed on the structure.

In the illustrated example, substrate 502 includes a source region 514, a drain region 516, and a channel region 518. Although illustrated as a horizontal structure, structures and devices in accordance with examples of the disclosure can include vertical and/or three-dimensional structures and devices, such as FinFET devices.

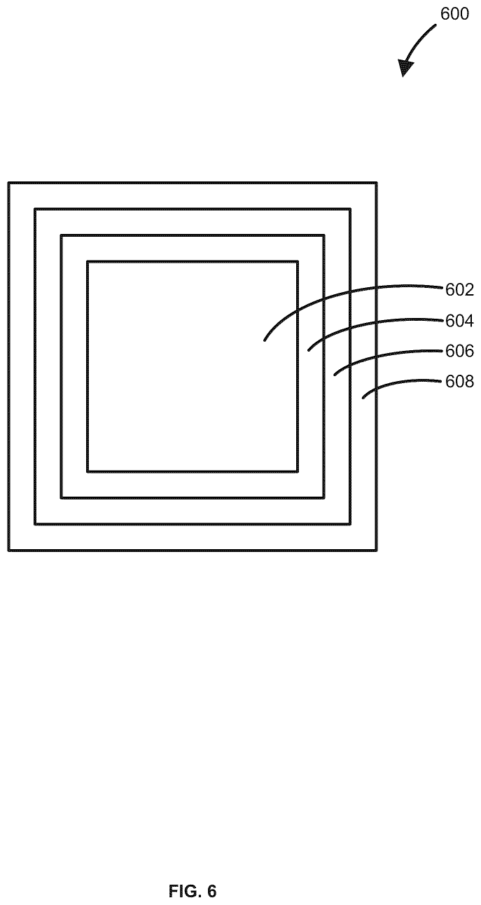

FIG. 6 illustrates another structure 600 in accordance with examples of the disclosure. Structure 600 is suitable for gate all around field effect transistor (GAA FET) (also referred to as lateral nanowire FET) devices and the like.

In the illustrated example, structure 600 includes semiconductor material 602, dielectric material 604, a layer comprising one or more of vanadium boride and vanadium phosphide 606, and a conducting layer 608. Structure 600 can be formed overlying a substrate, including any substrate materials described herein.

Semiconductor material 602 can include any suitable semiconducting material. For example, semiconductor material 602 can include Group IV, Group III-V, or Group II-VI semiconductor material. By way of example, semiconductor material 602 includes silicon.

Dielectric material 604, layer comprising one or more of vanadium boride and vanadium phosphide 606, and conducting layer 608 can be the same or similar to dielectric or insulating material 405, layer comprising one or more of vanadium boride and vanadium phosphide 408 and conducting layer 410, described above. Layer comprising one or more of vanadium boride and vanadium phosphide 606 can be formed overlying semiconductor material 602 and/or underlying dielectric material 604 in accordance with further examples of the disclosure.

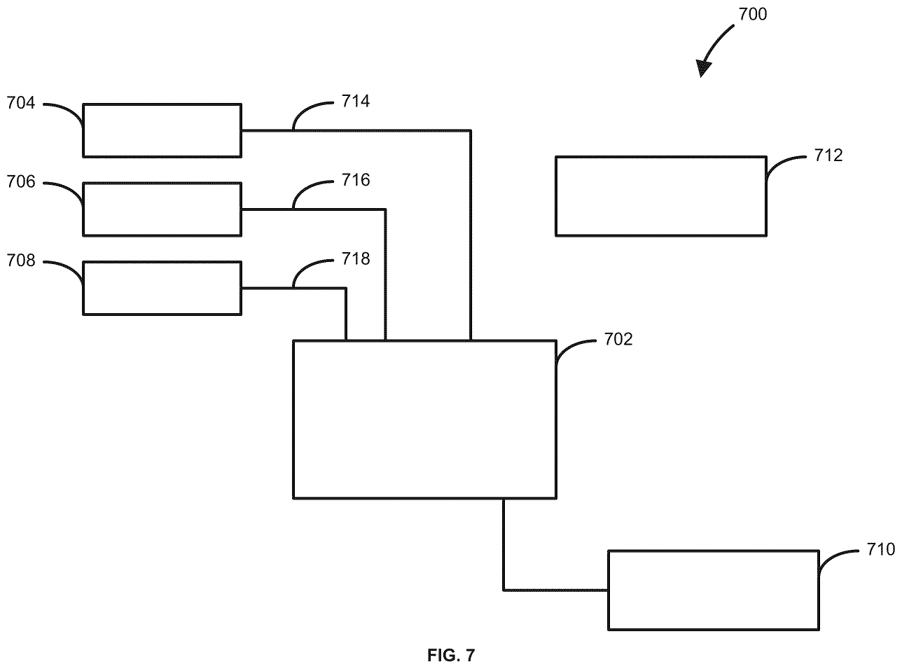

FIG. 7 illustrates a system 700 in accordance with yet additional exemplary embodiments of the disclosure. System 700 can be used to perform a method as described herein and/or form a structure or device portion as described herein.

In the illustrated example, system 700 includes one or more reaction chambers 702, a precursor gas source 704, a reactant gas source 706, a purge gas source 708, an exhaust source 710, and a controller 712.

Reaction chamber 702 can include any suitable reaction chamber, such as an ALD or CVD reaction chamber.

Precursor gas source 704 can include a vessel and one or more vanadium precursors as described herein-alone or mixed with one or more carrier (e.g., inert) gases. Reactant gas source 706 can include a vessel and one or more reactants (e.g., boron reactant, phosphorus reactant, and/or sulfur reactant) as described herein-alone or mixed with one or more carrier gases. Purge gas source 708 can include one or more inert gases as described herein. Although illustrated with three gas sources 704-708, system 700 can include any suitable number of gas sources. Gas sources 704-708 can be coupled to reaction chamber 702 via lines 714-718, which can each include flow controllers, valves, heaters, and the like.

Exhaust source 710 can include one or more vacuum pumps.

Controller 712 includes electronic circuitry and software to selectively operate valves, manifolds, heaters, pumps and other components included in the system 700. Such circuitry and components operate to introduce precursors, reactants, and purge gases from the respective sources 704-708. Controller 712 can control timing of gas pulse sequences, temperature of the substrate and/or reaction chamber, pressure within the reaction chamber, and various other operations to provide proper operation of the system 700. Controller 712 can include control software to electrically or pneumatically control valves to control flow of precursors, reactants and purge gases into and out of the reaction chamber 702. Controller 712 can include modules such as a software or hardware component, e.g., a FPGA or ASIC, which performs certain tasks. A module can advantageously be configured to reside on the addressable storage medium of the control system and be configured to execute one or more processes.

Other configurations of system 700 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 702. Further, as a schematic representation of a system, many components have been omitted for simplicity of illustration, and such components may include, for example, various valves, manifolds, purifiers, heaters, containers, vents, and/or bypasses.

During operation of reactor system 700, substrates, such as semiconductor wafers (not illustrated), are transferred from, e.g., a substrate handling system to reaction chamber 702. Once substrate(s) are transferred to reaction chamber 702, one or more gases from gas sources 704-708, such as precursors, reactants, carrier gases, and/or purge gases, are introduced into reaction chamber 702.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A system comprising:
one or more reaction chambers;
a precursor gas source comprising a vanadium precursor;
a reactant gas source comprising one or more of a boron reactant and a phosphorus reactant;
an exhaust source; and
a controller,
wherein the controller is configured to control gas flow into at least one of the one or more reaction chambers to form a layer comprising one or more of vanadium boride and vanadium phosphide overlying a surface of a substrate using a deposition process.

2. The system of claim 1, wherein the boron reactant comprises one or more of a borane, a borohydride, a boron halide, an alkyl boron compound, an amino boron compound, an amido boron compound, a compound comprising one or more borane adducts, a compound comprising one or more borohydride adducts, and mixed substituted boron compounds.

3. The system of claim 1, wherein the vanadium precursor comprises one or more of a vanadium halide, a vanadium oxyhalide, a vanadium organometallic compound, a vanadium metal organic compound, a vanadium beta-diketonate compound, a vanadium cyclopentadienyl compound, a vanadium alkoxide compound, a vanadium dialkylamido compound, a vanadium amidinate compound, a DAD ligand compound, where DAD is represented by 1,4-diaza-1,3-butadiene (RN=CR′CR′=NR, R=alkyl, aryl, R′=H, alkyl), and a vanadium heteroleptic or mixed ligand compound.

4. The system of claim 1, wherein the vanadium precursor comprises a vanadium halide.

5. The system of claim 1, wherein the boron reactant comprises a borane.

6. The system of claim 1, wherein the phosphorus reactant comprises one or more of phosphine, tetraphosphorus (P₄), a phosphorus halide, an alkyl phosphorus compound, an amino phosphorus compound, and an amido phosphorus compound.

7. The system of claim 1, wherein the controller is configured to provide a sulfur reactant, from a sulfur reactant source, to the reaction chamber.

8. The system of claim 7, wherein the sulfur reactant comprises one or more of hydrogen sulfide (H₂S), sulfur (S₈), a sulfur halide, a thiol (e.g., alkyl and aryl thiol), compounds including disulfide bonds, compounds including sulfur-alkyl group bonds, and compounds represented by the formula R—S—S—R′, wherein R and R′ are independently selected from aliphatic (e.g., C1-C8) and aromatic groups.

9. The system of claim 8, wherein the sulfur reactant comprises hydrogen sulfide.

10. The system of claim 1, wherein the controller is configured to provide a continuous flow of at least one of the precursor or the reactant.

11. The system of claim 1, wherein the controller is configured to perform a cyclical deposition process.

12. The system of claim 1, wherein the controller is configured to provide the vanadium precursor to the reaction chamber and provide the boron reactant and/or the phosphorus reactant to the reaction chamber separated by a purge step.

13. The system of claim 1, wherein the one or more of vanadium boride and vanadium phosphide further comprises a rare earth metal boride.

14. The system of claim 1, wherein the precursor gas source further comprises a carrier gas.

15. The system of claim 1, wherein the reactant gas source further comprises a carrier gas.

16. The system of claim 1, wherein the one or more of vanadium boride and vanadium phosphide further comprises another metal boride.
